(19) United States
(12) Patent Application Publication
(10) Pub. No.: US 2025/0255147 A1
(43) Pub. Date: Aug. 7, 2025

(54) DISPLAY PANEL AND DISPLAY DEVICE

(71) Applicant: WUHAN CHINA STAR OPTOELECTRONICS SEMICONDUCTOR DISPLAY TECHNOLOGY CO., LTD., Wuhan, Hubei (CN)

(72) Inventor: Yanqiang DUAN, Wuhan, Hubei (CN)

(73) Assignee: WUHAN CHINA STAR OPTOELECTRONICS SEMICONDUCTOR DISPLAY TECHNOLOGY CO., LTD., Wuhan, Hubei (CN)

(21) Appl. No.: 18/693,621

(22) PCT Filed: Jan. 8, 2024
(86) PCT No.: PCT/CN2024/071175

§ 371 Date: Mar. 20, 2024

(30) Foreign Application Priority Data
Dec. 26, 2023 (CN) 202311816803.X

(51) Int. Cl. H10K 59/80; H10K 59/131; H10K 59/95; H10K 102/00

(52) U.S. Cl. CPC H10K 59/873; H10K 59/131; H10K 59/95; H10K 2102/311

(57) ABSTRACT

Embodiments of the present application disclose a display panel and a display device, a panel body of the display panel has a main body portion, a bending portion, and a bonding portion, the bending portion is connected to the main body portion, edge subportions of the bending portion are disposed at both ends of the bending portion and close to a side of the main body portion, and the panel body includes a first inorganic layer, a first organic layer, and a second inorganic layer, the first organic layer is spaced between the first inorganic layer and the second inorganic layer within the edge subsections, or the second inorganic layer is disposed outside the edge subsections.

### TECHNICAL FIELD

The present disclosure relates to the field of display, and in particular to a display panel and a display device.

### BACKGROUND

At present, the panel body of the display panel is prepared by cutting and separating from the motherboard and then further cutting according to the shape requirements of different products. During the cutting, cracks are prone to occur at the edges of the panel body. Moreover, in curved products, in order to facilitate the bending of the bending portion of the panel body, the edges of the bending portion of the panel body are curved cut to form an L-shaped cut (L-Cut), and the L-shaped cut is partially warped, which makes the L-Cut edge of the bending portion of the panel body more prone to stress concentration. The cracks generated during the cutting extend to the wiring region within the bending portion of the panel body, which affects the product quality of the display panel.

Therefore, there is a need for a display panel and a display device to solve the above technical problems.

### SUMMARY

The present application provides a display panel that can alleviate the present technical problems of the product quality of the display panel caused by stress concentration in the L-shaped cut portion of the bending portion of the panel body and the extension of the cutting cracks to the wiring region within the bending portion.

In order to solve the above problems, the present application provides the following technical solutions.

The present application provides a display panel, including a panel body, in which the panel body includes a main body portion, a bonding portion disposed on a backlight side of the main body portion, and a bending portion connected between the main body portion and the bonding portion, connected to a first side of the main body portion, and including a plurality of edge subportions, in which the edge subportions are disposed at both ends of the bending portion in a first direction and the edge subportions are disposed on a side of the bending portion close to the main body portion, and the first direction is parallel to a direction of extension of the first side of the main body portion, in which the panel body includes:
a substrate disposed in the main body portion, the bending portion and the bonding portion;
a first inorganic layer disposed on a side of the substrate;
a second inorganic layer disposed on a side of the first inorganic layer away from the substrate; and
a first organic layer disposed between the first inorganic layer and the second inorganic layer;
in which the first organic layer is spaced between the first inorganic layer and the second inorganic layer within the edge subportions; or
the second inorganic layer is disposed outside the edge subportions and the second inorganic layer is disposed between two edge subportions in the first direction.

The present application also provides a display device comprising a display panel, in which the display panel includes a panel body, and the panel body includes a main body portion, a bonding portion disposed on a backlight side of the main body portion, and a bending portion connected between the main body portion and the bonding portion and connected to a first side of the main body portion, in which the bending portion includes a plurality of edge subportions disposed on a side of the bending portion close to the main body portion at both ends of the bending portion in a first direction, in which the first direction is parallel to a direction of extension of the first side of the main body portion, in which the panel body includes:
a substrate, disposed in the main body portion, the bending portion and the bonding portion;
a first inorganic layer, disposed on a side of the substrate;
a second inorganic layer, disposed on a side of the first inorganic layer away from the substrate; and
a first organic layer, disposed between the first inorganic layer and the second inorganic layer;
in which the first organic layer is spaced between the first inorganic layer and the second inorganic layer within the edge subportions; or
the second inorganic layer is disposed outside the edge subportions and the second inorganic layer is disposed between two edge subportions in the first direction.

### BRIEF DESCRIPTION OF THE DRAWINGS

FIG. 1 is a microscopic top view of an edge subportion of a display panel in the prior art.

FIG. 2 is a schematic diagram of a sliced structure of an edge subportion of a display panel in the prior art.

FIG. 3 is a schematic diagram of a first structure of a display panel provided by an embodiment of the present application.

FIG. 4 is a schematic structural diagram of an edge subportion of a display panel provided by an embodiment of the present application.

FIG. 5 is a schematic diagram of a second structure of a display panel provided by an embodiment of the present application.

FIG. 6 is a schematic diagram of a first structure of an edge subportion of a display panel provided by an embodiment of the present application.

FIG. 7 is a schematic diagram of a second structure of an edge subportion of a display panel provided by an embodiment of the present application.

FIG. 8 is a schematic diagram of a third structure of an edge subportion of a display panel provided by an embodiment of the present application.

FIG. 9 is a schematic diagram of a fourth structure of an edge subportion of a display panel provided by an embodiment of the present application.

FIG. 10 is a schematic diagram of a fifth structure of an edge subportion of a display panel provided by an embodiment of the present application.

FIG. 11 is a schematic diagram of a sixth structure of an edge subportion of a display panel provided by an embodiment of the present application.

FIG. 12 is a schematic diagram of a seventh structure of an edge subportion of a display panel provided by an embodiment of the present application.

FIG. 13 is a schematic diagram of a first structure of a bending portion of a display panel provided by an embodiment of the present application.

FIG. 14 is a schematic structural diagram of a first groove and a second groove within an edge subportion of a display panel provided by an embodiment of the present application.

FIG. 15 is a schematic diagram of a second structure of a bending portion of a display panel provided by an embodiment of the present application.

FIG. 16 is a schematic structural diagram of a first groove within an edge subportion of a display panel provided by an embodiment of the present application.

FIG. 17 is a schematic structural diagram of a protection layer of a display panel provided by an embodiment of the present application.

FIG. 18 is a schematic structural diagram of a display device provided by an embodiment of the present application.

### DETAILED DESCRIPTION

The present application provides a display panel and a display device. In order to make the object(s), technical solutions and effect(s) of the present application more clear and explicit, the application is further described in detail hereinafter with reference to the drawings and by way of embodiments. It should be understood that the specific embodiments described herein are only for explaining the present application and are not intended to limit the present application.

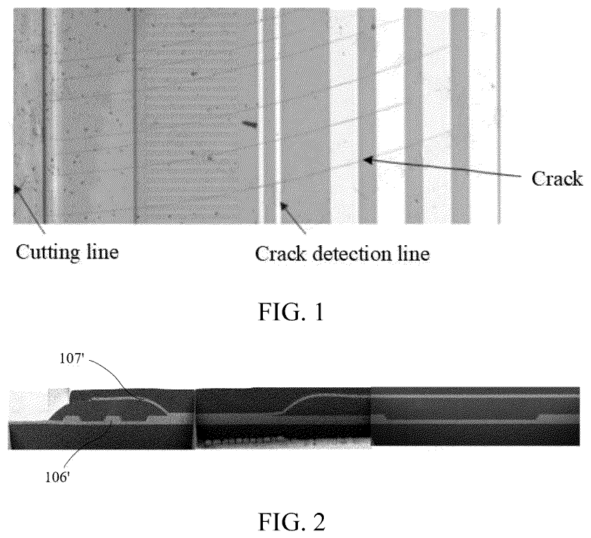

At present, the edge of the bending portion of the panel body is raised, resulting in the edge stress of the bending portion. As shown in FIGS. 1 and 2, the first inorganic layer 106′ and the second inorganic layer 107′ have direct contact within the edge subportion (the edge of the curved part of the panel body), and an inorganic layer formed by the first inorganic layer 106′ and the second inorganic layer 107′ has a thickness of from 1.8 to 2.2 microns, which is too thick and is prone to cracking under stress, thereby causing cracks generated during the cutting to extend to the wiring region within the bending portion (e.g., to the crack detection line(s)), resulting in technical problems that affect the product quality of the display panel.

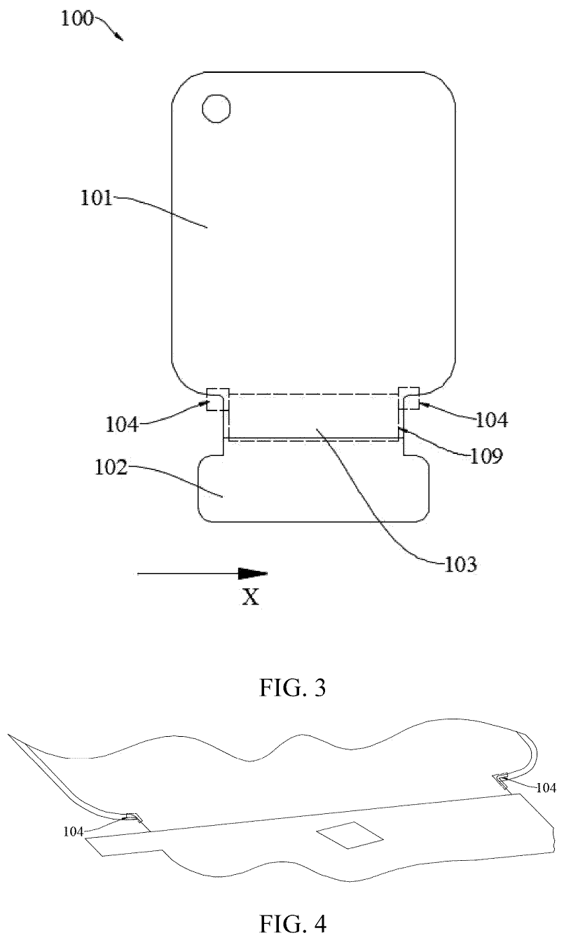

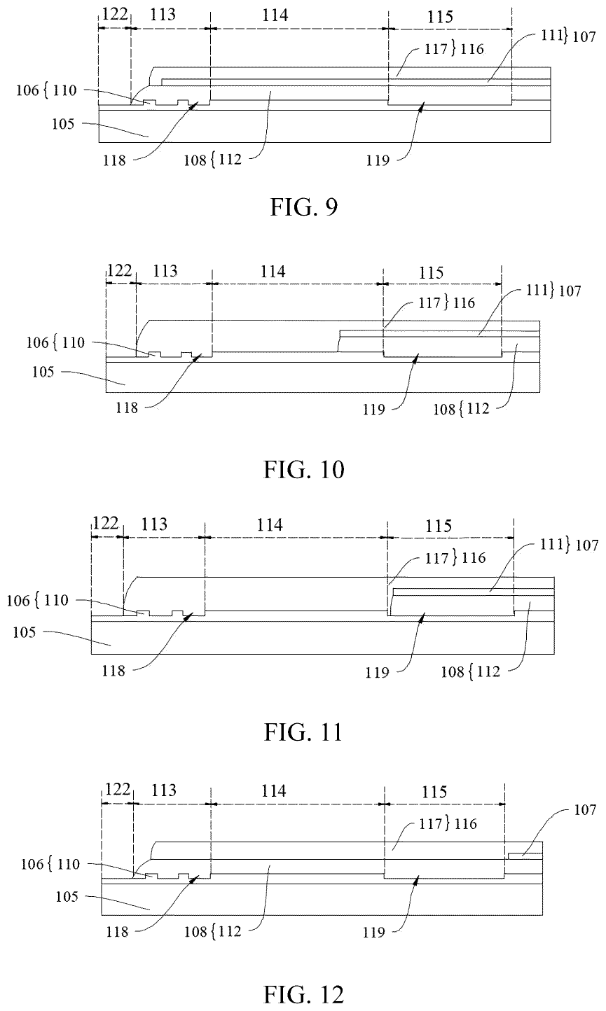

Referring to FIGS. 3 to 14, embodiments of the present application provide a display panel 10 including a panel body 100. The panel body 100 has a main body portion 101, a bonding portion 102 disposed on a backlight side of the main body portion 101, and a bending portion 103 connected between the main body portion 101 and the bonding portion 102. The bending portion 103 is connected to a first side of the main body portion 101. The bending portion 103 includes at least one edge subportion 104. The edge subportions 104 are disposed at both ends of the bending portion 103 in a first direction X and the edge subportions 104 are disposed on a side of the bending portion 103 close to the main body portion 101. The first direction X is parallel to the extension direction of the first side of the main body portion 101.

Referring to FIG. 3 and FIG. 4, along the first direction X, the main body portion 101 has a first width, the bending portion 103 has a second width on the side close to the main body portion 101, and the first width is larger than the second width. In order to achieve a change in the width of the first width of the panel body 100 on the first side of the main body portion 101 and the second width portion of the bending portion 103 on the side close to the main body portion 101, it is necessary to cut the side of the edge of the bending portion 103 close to the main body portion 101, thereby forming a L-shaped cut portion, and the L-shaped cut portion is the edge subportions 104.

Referring to FIG. 3, the bending portion 103 includes the edge subportions 104 and wiring subportions 109. The wiring subportions 109 are disposed between two the edge subportions 104 in the first direction X. That is, the edge subportions 104 are disposed on both sides of the wiring subportions 109 in the first direction X.

The panel body 100 includes:
a substrate 105, disposed in the main body portion 101, the bending portion 103 and the bonding portion 102;
a first inorganic layer 106, disposed on a side of the substrate 105;
a second inorganic layer 107, disposed on a side of the first inorganic layer 106 away from the substrate 105;
a first organic layer 108, disposed between the first inorganic layer 106 and the second inorganic layer 107;
the first organic layer 108 is spaced between the first inorganic layer 106 and the second inorganic layer 107 within the edge subportions 104; or
the second inorganic layer 107 is disposed outside the edge subportions 104 and the second inorganic layer 107 is disposed between two edge subportions 104 in the first direction X.

In the embodiments of the present application, the first organic layer 108 is configured such that it is spaced between the first inorganic layer 106 and the second inorganic layer 107 in the edge subportions 104 or the second inorganic layer 107 is disposed away from the edge subportions 104, thereby avoiding the contact of the first inorganic layer 106 and the second inorganic layer 107 at the edge subportions 104 and the formation of an overlapped inorganic layer that is too thick. Thereby, the cracks easily generated during the cutting are reduced and quality of the display panel is improved.

The technical solutions of the present application are now described in connection with specific embodiments.

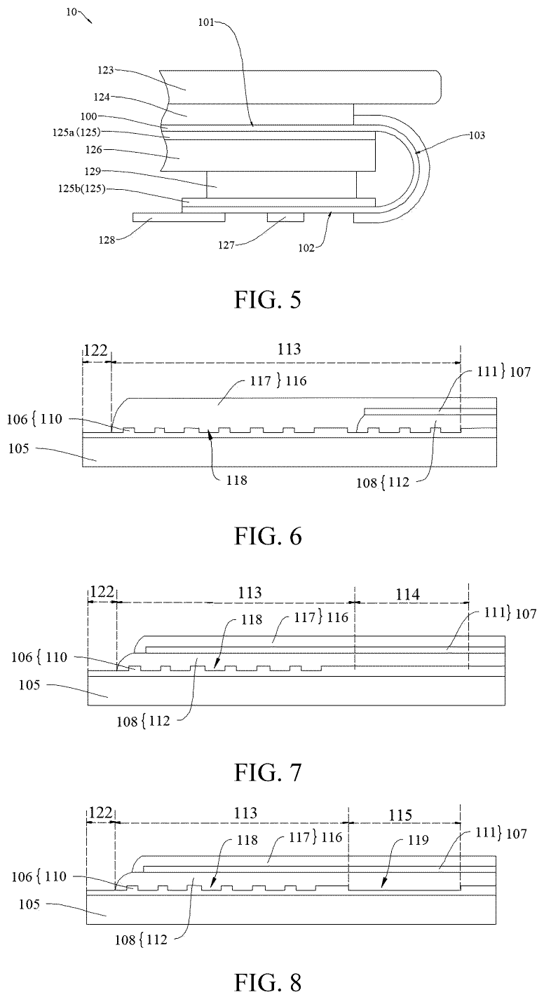

Referring to FIG. 5, in the present embodiment, the backlight side of the main body portion 101 is a side far away from the light-out side of the main body portion 101. The bending portion 103 is connected to the first side of the main body portion 101, and within the panel body 100, the first organic layer 108 is spaced between the first inorganic layer 106 and the second inorganic layer 107.

In some embodiments, the first inorganic layer 106 is disposed at least within the main body portion 101 and the bending portion 103. Within the bending portion 103, the first inorganic layer 106 is disposed within the wiring subportions 109 and the edge subportions 104.

In some embodiments, the second inorganic layer 107 is disposed at least within the main body portion 101 and the bending portion 103. Within the bending portion 103, the second inorganic layer 107 is disposed at least within the wiring subportions 109.

In some embodiments, the first organic layer 108 is disposed at least within the main body portion 101 and the bending portion 103. Within the bending portion 103, the first organic layer 108 is disposed at least within the wiring subportions 109.

Referring to FIGS. 6 to 9, in some embodiments, the first inorganic layer 106 includes a first subsegment 110 disposed in the edge subportions 104. When the second inorganic layer 107 is disposed in the wiring subportions 109, the second inorganic layer 107 includes a second subsegment 111, the first organic layer 108 includes a first organic subsegment 112. The first organic subsegment 112 is spaced between the first subsegment 110 and the second subsegment 111, which facilitates the spacing of the first inorganic layer 106 from the second inorganic layer 107. In addition, it avoids the contact between the first inorganic layer 106 and the second inorganic layer 107 and high thickness of the inorganic layer formed by the direct superposition of the two layers (106 and 107), thereby reducing the generation of cracks and improving the product quality of the display panel 10.

Referring to FIG. 5, FIG. 10 and FIG. 12, in some embodiments, the bending portion 103 further includes a cutting subportion 122 disposed on a side of the edge subportions 104 of the bending portion 103 away from the wiring subportions 109 of the bending portion 103. The substrate 105 and the first inorganic layer 106 are disposed within the cutting subportion 122. The cutting subportion 122 is the remaining of a cutting region after the cutting of the panel body 100.

In some embodiments, the cutting subportion 122 consists only of the substrate 105 and the first inorganic layer 106.

Referring to the edge subsections 104 shown in FIGS. 6 to 11, in some embodiments, the first inorganic layer 106 has a first end surface disposed within the edge subportions 104 in a direction from the edge subportions 104 to the wiring subportions 109, and the second inorganic layer 107 has a second end surface disposed within the edge subportions 104 in the direction from the edge subportions 104 to the wiring subportions 109. In the direction from the edge subportion 104 to the wiring subportions 109, the second end surface of the second inorganic layer 107 is disposed between the first end surface of the first inorganic layer 106 and the wiring subportions 109. By setting the second end surface of the second inorganic layer 107 be closer to the wiring subportions 109 than that of the first end surface, a thickness of the inorganic layer of the bending portion 103 close to the cutting subportion is reduced, which is conducive to reducing the generation of cracks and improving the product quality of the display panel 10.

Referring to FIGS. 6 to 11, in some embodiments, each of the edge subportions 104 includes a first region 113 along the direction from one of the edge subportions 104 to the wiring subportions 109. The first subsegment 110 includes at least one first groove 118. The first groove 118 is disposed within the first region 113 of the edge subportions 104, and the first groove 118 extends in a second direction parallel to the extension direction of a side of the edge subportions 104 away from the wiring subportions 109. With the arrangement of the first groove 118, it blocks the cracks generated by cutting in the first direction X from extending towards the wiring subportions 109 while reducing the thickness of the first subsegment 110 to avoid the stress concentration, thereby enhancing the product quality of the display panel 10.

Referring to FIGS. 6 to 11, 13 and 15, in some embodiments, a plurality of the first grooves 118 within the first region 113 are sequentially arranged in the direction from the edge subportions 104 to the wiring subportions 109, which is conducive to sufficiently blocking cracks generated by cutting from extending towards the wiring subportions 109, thereby enhancing the product quality of the display panel 10.

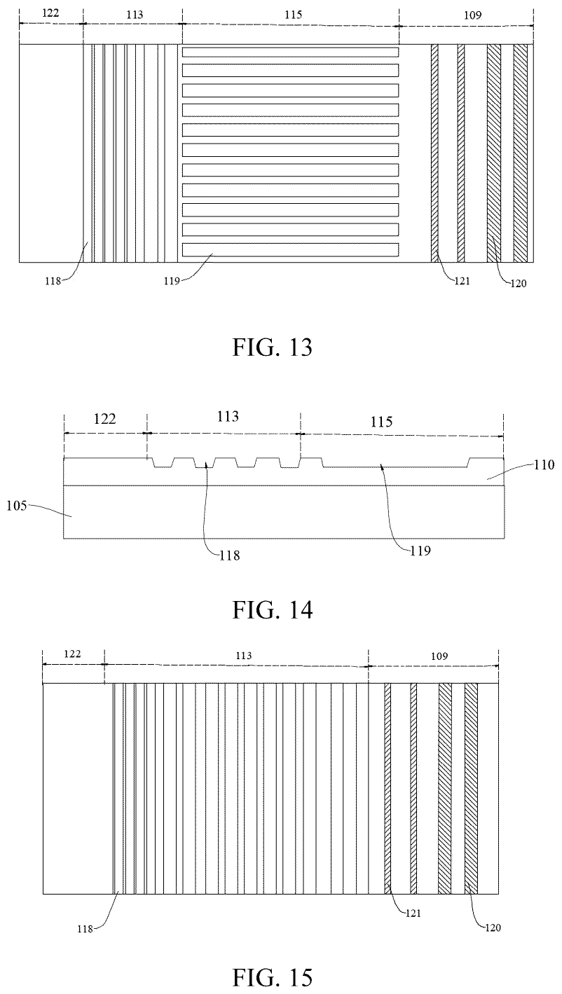

Referring to FIG. 3, FIG. 13 and FIG. 15, in some embodiments, the widths of the first grooves 118 disposed close to the edge of the bending portion 103 in the direction from the edge subportions 104 to the wiring subportions 109 are less than the widths of the first grooves 118 provided proximate the wiring subportions 109. The widths of the first grooves 118 are average of the distances between opposite sides of the first grooves 118 in the direction from the edge subportions 104 to the wiring subportions 109. By setting smaller widths of the first grooves 118 close to the edge of the bending portion 103, it is conducive to setting more first grooves 118 in the same width in the direction from the edge subportions 104 to the wiring subportions 109, so as to enhance the blocking effect of the first grooves 118 on the cracks generated during the cutting, and to enhance the product quality of the display panel 10.

In some embodiments, the widths of the first grooves 118 gradually increase along the direction from the edge subportions 104 to the wiring subportions 109 in the direction from the edge subportions 104 to the wiring subportions 109.

Referring to FIG. 13 and FIG. 15, in some embodiments, in the direction from the edge subportions 104 to the wiring subportions 109, the distance between the first grooves 118 provided close to the edge of the bending portion 103 is less than the distance between the first grooves 118 provided close to the wiring subportions 109, which is conducive to setting more first grooves 118 in the same width in the direction from the edge subportions 104 to the wiring subportions 109, so as to enhance the blocking effect of the first grooves 118 on cracks generated during cutting, and to enhance the product quality of the display panel 10.

In some embodiments, the distance between the first grooves 118 increases gradually along the direction from the edge subportions 104 to the wiring subportions 109 in the direction from the edge subportions 104 to the wiring subportions 109.

In some embodiments, the first grooves 118 are vertically and throughly penetrated in the direction of a side of the edge subportions 104 proximate the main body portion 101 and a side of the edge subportions 104 proximate the bonding portion 102, that is, each of the first grooves 118 is a through groove, which facilitates sufficient blocking of cracks generated by cutting in the direction from the edge subportions 104 to the wiring subportions 109 from extending towards the wiring subportions 109, so as to enhance the product quality of the display panel 10.

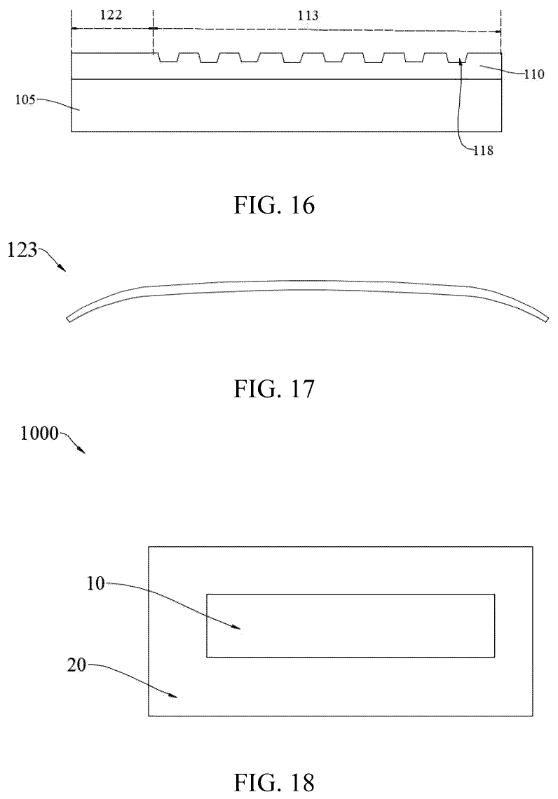

Referring to FIG. 3, FIG. 6 and FIG. 15, and FIG. 16, in some embodiments, the edge subportions 104 include only the first region 113.

Referring to FIGS. 7, 9 to 13, in some embodiments, the edge subportions 104 further include second regions 114 disposed on a side of the first region 113 close to the wiring subportions 109 along the direction from the edge subportions 104 to the wiring subportions 109. The first grooves 118 are disposed outside the second regions 114, that is, there are no first grooves 118 within the second regions 114.

Referring to FIGS. 8 to 14, in some embodiments, the edge subportions 104 further include at least one third region 115 disposed at the side of the first region 113 proximate to the wiring subportions 109 along the direction from the edge subportions 104 to the wiring subportions 109. The first subsegment 110 further includes a plurality of second grooves 119. The second grooves 119 are disposed within the third region 115, extending along the direction from the edge subportions 104 to the wiring subportions 109. The plurality of the second grooves 119 are sequentially arranged. The arrangement of the second grooves 119 facilitates the blocking of cracks generated by cutting in the second direction, thereby enhancing the product quality of the display panel 10.

Referring to FIGS. 8 to 14, in some embodiments, the second grooves 119 are disposed only within the third region 115. That is, the second grooves 119 are disposed outside of the second regions 114, i.e., there are no the second grooves 119 within the second regions 114.

Referring to FIGS. 7 to 9, in some embodiments, the first subsegment 110 is disposed within the first region 113 and the second subsegment 111 is disposed within the first region 113.

In some embodiments, the first subsegment 110 is disposed within the first region 113 and the second regions 114, and the second end surface of the second inorganic layer 107 is disposed within the second regions 114.

In some embodiments, the first subsegment 110 is disposed within the first region 113 and the third region 115, and the second end surface of the second inorganic layer 107 is disposed within the third region 115.

In some embodiments, referring to FIG. 10, the first subsegment 110 is disposed within the first region 113, the second regions 114, and the third region 115, the second subsegment 111 is disposed within the second regions 114 and the third region 115, and the second end surface of the second inorganic layer 107 is disposed within the second regions 114. Alternatively, referring to FIG. 11, the first subsegment 110 is disposed within the first region 113, the second regions 114 and the third region 115, and the second subsegment 111 is disposed only within the third region 115, i.e., the second end surface of the second inorganic layer 107 is disposed within the third region 115.

Referring to FIGS. 6 to 9, in some embodiments, a positive projection of the second end surface of the second inorganic layer 107 on the first subsegment 110 is at least partially disposed within any one of the first grooves 118. For example, when the first grooves 118 are through grooves, the positive projection of the second end surface of the second inorganic layer 107 on the first subsegment 110 is disposed within any one of the first grooves 118. By the setting of the projection of the second end surface of the second inorganic layer 107 being disposed within the first grooves 118, it is favorable to reduce the total thickness of the first inorganic layer 106 and the second inorganic layer 107 at one end near the cutting region, reduce crack generation, and improve the product quality of the display panel 10. When the first subsegment 110 includes a plurality of the first grooves 118 and the positive projection of the second end surface of the second inorganic layer 107 is at least partially disposed within any one of the first grooves 118, it is preferable that the positive projection is disposed within one of the first grooves 118 furthest away from the wiring subportions 109.

Referring to FIGS. 6 to 11, in some embodiments, the first organic layer 108 includes a first organic subsegment 112 disposed in the edge subportions 104, and the first organic subsegment 112 is spaced between the first subsegment 110 and the second subsegment 111, which is conducive to spacing the first inorganic layer 106 within the edge subportions 104 from the second inorganic layer 107, and to avoiding the contact and the formation of the thick inorganic layer formed by direct superposition of the two layers, thereby reducing the generation of cracks and improving the product quality of the display panel 10.

Referring to FIGS. 6 to 11, in some embodiments, the first organic subsegment 112 may be disposed within the first region 113 or, alternatively, the first organic subsegment 112 may be disposed within the first region 113 and the second regions 114, or, alternatively, the first organic subsegment 112 may be disposed within the first region 113 and the third region 115, or, alternatively, the first organic subsegment 112 may be disposed within the first region 113, the second regions 114, and the third region 115. The first organic subsegment 112 has a third end surface disposed within the edge subportions 104 in a direction from the edge subportions 104 to the wiring subportions 109. In order to act as a spacer between the first subsegment 110 and the second subsegment 111, the third end surface of the first organic subsegment 112 is disposed on a side of the second end surface of the second inorganic layer 107 away from the wiring subportions 109. Optionally, the positive projection of the third end surface of the first organic subsegment 112 on the substrate at least partially coincides with the positive projection of the second end surface of the second inorganic layer 107 on the substrate. Preferably, the first organic subsegment 112 may not cover at least a portion of the first subsegment 110 disposed within the first region 113 in proximity to the cutting subportion 122, which facilitates the reduction of the number of layers in proximity to the cutting subportion 122, thereby reducing the total thickness of the layers in the edge subportions 104 in proximity to the cutting subportion 122, reducing the generation of cracks and improving the product quality of the display panel 10. For example, when the edge subportions 104 include the first regions 113, the third end surface of the first organic subsegment 112 is disposed within the first regions 113 and between a side edge of the edge subportions 104 close to the cutting subportion 122 and a second end surface of the second inorganic layer 107; when the edge subportions 104 include the first regions 113 and the second regions 114, the third end surface of the first organic subsegment 112 is disposed within the second regions 114; when the edge subportions 104 include the first regions 113 and the third region 115, the third end surface of the first organic subsegment 112 is disposed within the third region 115; and when the edge subportions 104 include the first regions 113, the second regions 114 and the third region 115, the third end surface of the first organic subsegment 112 is disposed within the second regions 114 or the third region 115.

Referring to FIGS. 6 to 12, in some embodiments, a positive projection of the second subsegment 111 on the first organic subsegment 112 coincides with the first organic subsegment 112, or, the positive projection of the second subsegment 111 on the first organic subsegment 112 is disposed within the first organic subsegment 112 so that the first organic subsegment 112 sufficiently separates the first subsegment 110 from the second subsegment 111, which is conducive to reducing crack generation and improving the product quality of the display panel 10.

Referring to FIGS. 6 to 11, in some embodiments, the panel body 100 further includes a second organic layer 116 disposed on a side of the second inorganic layer 107 away from the substrate 105. The second organic layer 116 includes a second organic subsegment 117 disposed at the edge subportions 104. The second organic subsegment 117 at least contacts and covers the second subsegment 111. The second organic layer 116 is provided in a manner that facilitates the flattening of the surface of the edge subportions 104 away from the substrate 105, enhances the flexibility of the edge subportions 104 and protects the second inorganic layer 107, thereby reducing the crack generation and improving the product quality of the display panel 10.

Referring to FIGS. 6 and 11, in some embodiments, when the first organic subsegment 112 does not cover a portion of the first subsegment 110 close to the cutting subportion, i.e., when the first organic subsegment 112 exposes a portion of the first subsegment 110, the second organic subsegment 117 covers the second subsegment 111 and the first subsegment 110 exposed by the first organic subsegment 112, which favorably protects the first subsegment 110, thereby reducing the crack generation and improving the product quality of the display panel 10. The positive projection of the second organic subsegment 117 on the substrate 105 may coincide with the substrate within the edge subportions 104. Specifically, when the edge subportions 104 include the first regions 113, the second organic subsegment 117 is disposed within the first regions 113; when the edge subportions 104 include the first regions 113 and the second regions 114, the second organic subsegment 117 is disposed within the first regions 113 and within the second regions 114; or when the edge subportions 104 include the first regions 113, the second regions 114, and the third region 115, the second organic subsegment 117 is disposed within the first regions 113, the second regions 114, and the third region 115.

Referring to FIG. 12, in some embodiments, within the bending portion 103, the first inorganic layer 106 is disposed in the wiring subportions 109 and the edge subportions 104, and the second inorganic layer 107 is disposed only in the wiring subportions 109. As the second inorganic layer 107 is set to avoid the edge subportions 104, it facilitates the reduction of the total thickness of the inorganic layer within the edge subportions 104, reduces the generation of cracks, and improves the product quality of the display panel 10.

Referring to FIG. 5, FIG. 13 and FIG. 15, in some embodiments, the panel body 100 includes a first type wiring 120 and a second type wiring 121. The first type wiring 120 includes a first wiring segment disposed within the main body portion 101 and a second wiring segment disposed within the wiring subportions 109, and the second type wiring 121 includes a third wiring segment disposed within the main body portion 101 and a fourth wiring segment disposed within the wiring subportions 109. The main body portion 101 includes a display region and a non-display region surrounding the display region, the first wiring segment is disposed within the non-display region, and the first wiring segment is disposed on at least one side of the display region in the first direction X. The first type wiring 120 may be a gate drive line. The second type wiring 121 is disposed within the non-display region, the third wiring segment is disposed on the side of the first wiring segment away from the display region, and the fourth wiring segment is disposed on the side of the second wiring segment close to the edge subportions 104.

Referring to FIG. 12, in some embodiments, within the bending portion 103, the positive projection of the second inorganic layer 107 on the substrate 105 covers the positive projection of the second type wiring 121 on the substrate 105 when the second inorganic layer 107 is disposed only on the wiring subportions 109. In the direction from the edge subportions 104 to the wiring subportions 109, the distance between the positive projection of the second end surface of the second inorganic layer 107 on the substrate and the positive projection of the second type wiring 121 on the substrate 105 is greater than or equal to 100 μm, and less than or equal to 200 μm.

In some embodiments, the panel body 100 includes a thin film transistor layer disposed between the substrate 105 and the first organic layer 108. The thin film transistor layer includes a gate layer, and a source-drain layer disposed on a side of the gate layer away from the substrate 105. The panel body 100 includes the first inorganic layer 106, and the first inorganic layer 106 includes a first inorganic sublayer and a second inorganic sublayer. The first inorganic sublayer is disposed between the gate layer and the source-drain layer, and the second inorganic sublayer is disposed between the source-drain layer and the first organic layer 108.

In some embodiments, the substrate 105 may be a flexible substrate. For example, the substrate 105 may be a polyimide substrate. When the substrate 105 is a flexible substrate, the substrate 105 includes a first flexible sub-substrate, an intermediate layer, an adhesive layer, and a second flexible sub-substrate. The first flexible sub-substrate and the second flexible sub-substrate may be formed from the same material, such as polyimide. The intermediate layer may be formed from, for example, an inorganic material including at least one of SiOx and SiNx. The adhesive layer may be formed from hydrogenated amorphous silicon (a-Si: H).

In some embodiments, the panel body 100 further includes a buffer layer disposed between the substrate 105 and the thin film transistor layer. The buffer layer may include one or more inorganic insulating layers including, for example, materials such as silicon oxide or silicon nitride. The buffer layer may provide a planarizing layer on the upper surface of the substrate 105 and may stop or prevent impurities and moisture from penetrating from the substrate 105 into a light emitting layer. Specifically, the buffer layer includes a first sub-buffer layer formed, for example, from silicon nitride, and a second sub-buffer layer formed, for example, from silicon oxide. The second sub-buffer layer and the first sub-buffer layer may be made from silicon nitride having the same film quality (e.g., the same density and the same film stress), and an oxide film may be positioned at the interface between the second sub-buffer layer and the first sub-buffer layer. In practical use, the thickness of the first sub-buffer layer may be from 50 nm to 100 nm, and the thickness of the second sub-buffer layer may be about 100 nm to 300 nm.

In some embodiments, the thin film transistor layer further includes a semiconductor layer disposed on the side of the buffer layer away from the substrate 105, and the semiconductor layer includes a semiconductor that can be formed from polysilicon. The semiconductor is divided into a channel region, and a source region and a drain region formed on both sides of the channel region, respectively. The channel region of the semiconductor is polysilicon without doped impurities, i.e., an intrinsic semiconductor. The source region and the drain region are polysilicon doped with conductive impurities, i.e., impurity semiconductors. The impurities doped in the source region and the drain region may be any one of P-type impurities and N-type impurities.

In some embodiments, the gate layer includes a first subgate layer disposed on the side of the semiconductor layer away from the substrate 105, and the first subgate layer includes a first gate overlapping the channel region. The gate layer further includes a second subgate layer disposed on the side of the first subgate layer away from the substrate 105. The second subgate layer includes a second gate, and a positive projection of the second gate on the first gate layer may overlap the first gate. The first gate and the second gate may be formed as a plurality of layers or a single layer including a low resistance material such as Al, Ti, Mo, Cu, Ni, or alloys thereof, or a material having high corrosion resistance.

In some embodiments, the thin film transistor layer includes a first gate insulating layer disposed between the gate layer and the semiconductor layer. The gate layer further includes a second gate insulating layer disposed between the first subgate layer and the second subgate layer, and the first inorganic sublayer may include at least one of the first gate insulating layer and the second gate insulating layer.

In some embodiments, the first inorganic sublayer may be composed of the first gate insulating layer and the second gate insulating layer.

In some embodiments, the thin film transistor layer further includes an interlayer insulating layer disposed between the source-drain layer and the gate layer, and the second inorganic sublayer may be the interlayer insulating layer.

In some embodiments, the source-drain layer includes a source and a drain, the interlayer insulating layer and the first gate insulating layer. The second gate insulating layer include a source contact hole and a drain contact hole. The source region and the drain region are exposed through the source contact hole and the drain contact hole, respectively.

In some embodiments, the first type wiring 120 is disposed in at least one of the source-drain layer, the first subgate layer, and the second subgate layer. The second type wiring 121 is disposed in at least one of the source-drain layer, the first subgate layer, and the second subgate layer.

In some embodiments, the first organic layer 108 is used for insulation and flatarization. The first organic layer 108 may be selected from an organic material having a low dielectric constant (e.g., polyimide).

In some embodiments, the panel body 100 further includes a pixel defining layer disposed on a side of the first organic layer 108 away from the substrate 105, a light-emitting device layer disposed on a side of the pixel defining layer away from the substrate, and an encapsulation layer disposed on a side of the light-emitting device layer away from the substrate 105.

In some embodiments, the encapsulation layer may sequentially include a first inorganic encapsulation layer, a first organic encapsulation layer, and a second inorganic encapsulation layer disposed on the light emitting device layer along a direction away from the substrate 105. Alternatively, the encapsulation layer may sequentially include a first inorganic encapsulation layer, a first organic encapsulation layer, a second inorganic encapsulation layer, a second organic encapsulation layer, and a third inorganic encapsulation layer disposed on the light-emitting device layer along the direction away from the substrate 105. Alternatively, the encapsulation layer may sequentially include a first inorganic encapsulation layer, a first organic encapsulation layer, a second inorganic encapsulation layer, a second organic encapsulation layer, a third inorganic encapsulation layer, a third organic encapsulation layer, and a fourth inorganic encapsulation layer disposed on the light-emitting device layer along the direction away from the substrate 105.

In some embodiments, the panel body 100 further includes a touch layer disposed on the side of the first organic layer 108 away from the substrate 105. The touch layer includes a first touch metal layer, a second touch metal layer disposed on the side of the first touch metal layer away from the substrate 105, the second inorganic layer 107 spaced between the first touch metal layer and the second touch metal layer, and a second organic layer 116 disposed on a side of the second touch metal layer away from the substrate 105.

In some embodiments, the touch layer is disposed on a side of the encapsulation layer away from the substrate 105. The first touch metal layer may be provided directly on the encapsulation layer or, alternatively, a spacing layer is provided between the first touch layer and the encapsulation layer, and the spacing layer may include an inorganic spacing layer and/or an organic spacing layer.

Referring to FIG. 5 and FIG. 17, in some embodiments, the display panel 10 further includes a protection layer 123 disposed on the light-out side of the main body portion 101 of the panel body 100. The protection layer 123 is adhered to the panel body 100, and the curvature of the protection layer 123 at any point on a surface of a side away from the panel body 100 is not 0. As the protective layer 123 is adhered to the panel body 100, and the edge subportions 104 are adhered to the protection layer 123, the curvature at any point on a surface of a side of the edge subportions 104 close to the protection layer 123 is not 0, resulting in warping of the edge subportions 104 for adhering to the protection layer 123, which is more susceptible to stress concentration. The present application effectively reduces or even avoids cracks due to warping and stress concentration, while improves the product quality of the display panel 10, by the setting that the curvature at any point on the surface of the side of the edge subportions 104 proximate to the protection layer 123 is not 0, by spacing the first organic layer 108 between the first inorganic layer 106 and the second inorganic layer 107 within the edge subportions 104, or by setting the second inorganic layer 107 away from the edge subportions 104.

In some embodiments, the display panel 10 further includes a glue layer 124 disposed between the protection layer 123 and the second organic layer 116 for adhering and fixing the protection layer 123 to the panel body 100. The material of the glue layer 124 may be selected from a transparent optical adhesive.

Referring to FIG. 17, in some embodiments, the protection layer 123 is a cover plate, and the curvature of the cover plate at any point on a side surface away from the panel body 100 is not 0, i.e., the cover plate is a fully curved cover plate.

Referring to FIG. 5, in some embodiments, the display panel 10 further includes a flexible circuit board 128 and a chip 127 provided in the bonding portion 102.

Referring to FIG. 5, in some embodiments, the display panel 10 further includes a support layer 125 including a first support portion 125a and a second support portion 125b. The first support portion 125a is disposed on the backlight side of the main body portion 101, and the second support portion 125b is disposed on a side of the bonding portion 102 close to the first support portion 125a. The material of the support layer 125 may be a material such as stainless steel.

Referring to FIG. 5, in some embodiments, the display panel 10 further includes a heat dissipation layer 126 disposed between the first support portion 125a and the second support portion 125b. The heat dissipation layer 126 is used to enhance the heat dissipation performance and impact resistance of the display panel 10.

Referring to FIG. 5, in some embodiments, the display panel 10 further includes an adhesive layer 129 disposed between the heat dissipation layer 126 and the second support portion 125b, and the second support portion 125b is adhesively fixed to the heat dissipation layer 126 by the adhesive layer 129 so that the bonding portion 102 is fixed to the backlight side of the main body portion 101. The chip 127 and the flexible circuit board 128 are provided on a side of the bonding portion 102 away from the second support portion 125b.

The display panel 10 provided in the embodiments of the present application is configured by spacing the first organic layer 108 between the first inorganic layer 106 and the second inorganic layer 107 within the bending portion 103 or by setting the second inorganic layer 107 to avoid the edge subportions 104, preventing the contact between the first inorganic layer 106 and the second inorganic layer 107 at the edge subportions 104 from forming the thick inorganic layer by the superposition of the two inorganic layers 106 and 107, thereby reducing the generation of cracks and improving the product quality of the display panel 10.

Referring to FIG. 18, the present application also provides a display device 1000 including a display panel 10 as described in some of the foregoing embodiments.

In some embodiments, the display device 1000 further includes a device body 20 that is integrated with the display panel 10.

The specific structures of the display panel 10 are described with reference to any of the above embodiments of the display panel 10 and the accompanying drawings, and will not be repeated herein.

In this embodiment, the device body 20 may include a center frame, frame rubber, or the like. The display device 1000 may be a display terminal, such as a cell phone, a tablet, a TV, or the like, without limitation herein.

Embodiments of the present application disclose a display panel and a display device. The display panel includes a panel body, and the panel body has a main body portion, a bending portion and a bonding portion. The bending portion is connected to the main body portion, and the bending portion includes edge subportions. The edge subportions are disposed at both ends of the bending portion in a first direction and close to a side of the main body. The panel body includes: a substrate, a first inorganic layer disposed on a side of the substrate, a second inorganic layer disposed on a side of the first inorganic layer away from the substrate, and a first organic layer disposed between the first inorganic layer and the second inorganic layer. Within the edge subportions, the first organic layer is spaced between the first inorganic layer and the second inorganic layer, or the second inorganic layer is disposed outside the edge subportions. The present application avoids excessive thickness caused by direct superposition of the inorganic layers within the edge subportions by disposing the first organic layer between the first inorganic layer and the second inorganic layer within the edge subportions or by setting the second inorganic layer to avoid the edge subportions, thereby reducing the generation of cracks and improving the product quality of the display panel.

It is understood that, to a person of ordinary skill in the art, equivalent substitutions or changes may be made in accordance with the technical solutions of the present application and its inventive concept, and all such changes or substitutions shall fall within the scope of protection of the claims attached to the present application.

What is claimed is:

1. A display panel comprising
a panel body, and the panel body has a main body portion, a bonding portion disposed on a backlight side of the main body portion, and a bending portion connected between the main body portion and the bonding portion, wherein the bending portion is connected to a first side of the main body portion, and the bending portion comprises at least one edge subportion, wherein the edge subportions are disposed at both ends of the bending portion in a first direction and the edge subportions are disposed on a side of the bending portion close to the main body portion, wherein the first direction is parallel to a direction of extension of the first side of the main body portion, and wherein the panel body comprises:
a substrate disposed in the main body portion, the bending portion and the bonding portion;
a first inorganic layer disposed on a side of the substrate;
a second inorganic layer disposed on a side of the first inorganic layer away from the substrate; and
a first organic layer disposed between the first inorganic layer and the second inorganic layer;
wherein the first organic layer is spaced between the first inorganic layer and the second inorganic layer within the edge subportions; or
the second inorganic layer is disposed outside the edge subportions and the second inorganic layer is disposed between two edge subportions in the first direction.

2. The display panel of claim 1, wherein the first inorganic layer comprises a first subsegment disposed in the edge subportions, the second inorganic layer comprises a second subsegment disposed in the edge subportions, the first organic layer comprises a first organic subsegment disposed in the edge subportions, and the first organic subsegment is spaced between the first subsegment and the second subsegment.

3. The display panel of claim 2, wherein the bending portion further comprises a plurality of wiring subportions disposed between two edge subportions, the first inorganic layer has a first end surface disposed within the edge subportions, and the second inorganic layer has a second end surface disposed within the edge subportions, wherein in a direction from the edge subportions to the wiring subportions, the second end surface of the second inorganic layer is disposed between the first end surface of the first inorganic layer and the wiring subportions.

4. The display panel of claim 3, wherein the edge subportions comprise at least one first region along the direction from the edge subportions to the wiring subportions;
the first subsegment comprises at least one first groove, the first groove is disposed within the first region of the edge subportions, the first groove extends in a second direction parallel to a direction of extension of a side of the edge subportions away from the wiring subportions.

5. The display panel of claim 4, wherein the edge subportions further comprise at least one second region disposed on a side of a first region close to the wiring subportions along the direction from the edge subportions to the wiring subportions, the first groove is disposed outside the second region, and the first subsegment is disposed within the first region and the second region.

6. The display panel of claim 5, wherein the second end surface of the second inorganic layer is disposed within the second region.

7. The display panel of claim 5, wherein the edge subportions further comprise at least one third region along the direction from the edge subportions to the wiring subportions, and the third region is disposed on a side of the second region of the edge subportions close to the wiring subportions;
the first subsegment further comprises a plurality of second grooves, the second grooves are disposed within the third region, the second grooves extend along the direction from the edge subportions to the wiring subportions, and the plurality of the second grooves are sequentially arranged in the second direction.

8. The display panel of claim 7, wherein the first subsegment is further disposed within the third region and the second end surface of the second inorganic layer is disposed within the second region.

9. The display panel of claim 7, wherein the first subsegment is further disposed within the third region and the second end surface of the second inorganic layer is disposed within the third region.

10. The display panel of claim 4, wherein a plurality of the first grooves are sequentially arranged along the direction from the edge subportions to the wiring subportions within the first region.

11. The display panel of claim 4, wherein the edge subportions further comprise a third region along the direction from the edge subportions to the wiring subportions, and the third region is disposed on a side of the first region of the edge subportions close to the wiring subportions; and
wherein the first subsegment further comprises a plurality of second grooves, the second grooves are disposed within the third region, the second grooves extend along the direction from the edge subportions to the wiring subportions, and the plurality of the second grooves are sequentially arranged in the second direction.

12. The display panel of claim 11, wherein the first subsegment is further disposed within the third region and the second end surface of the second inorganic layer is disposed within the third region.

13. The display panel of claim 12, wherein the panel body further comprises a second organic layer disposed on a side of the second inorganic layer away from the substrate, and the second organic layer comprises a second organic subsegment disposed at the edge subportions; and
wherein the first organic subsegment exposes a portion of the first subsegment, and the second organic subsegment covers the second subsegment and covers the first subsegment exposed by the first organic subsegment.

14. The display panel of claim 1, wherein the first inorganic layer is disposed in the wiring subportions and the edge subportions of the bending portion, and the second inorganic layer is disposed only in the wiring subportions of the bending portion within the bending portion.

15. The display panel of claim 1, wherein the bending portion further comprises a cutting subportion disposed on a side of the edge subportions of the bending portion away from the wiring subportions of the bending portion, and the substrate and the first inorganic layer are disposed within the cutting subportion.

16. The display panel of claim 1, wherein the panel body comprises a thin film transistor layer disposed between the substrate and the first organic layer, wherein the thin film transistor layer comprises a gate layer, a source-drain layer disposed on a side of the gate layer away from the substrate, and the first inorganic layer, wherein the first inorganic layer comprises a first inorganic sublayer and a second inorganic sublayer, wherein the first inorganic sublayer is disposed between the gate layer and the substrate, and the second inorganic sublayer is disposed between the source-drain layer and the gate layer; and
wherein the panel body further comprises a touch layer disposed on a side of the first organic layer away from the substrate, wherein the touch layer comprises a first touch metal layer, a second touch metal layer disposed on a side of the first touch metal layer away from the substrate, the second inorganic layer spaced between the first touch metal layer and the second touch metal layer, and a second organic layer disposed on a side of the second touch metal layer away from the substrate.

17. The display panel of claim 16, wherein the display panel further comprises a protection layer disposed on a light-out side of the main body portion of the panel body, and the protection layer is adhered to the panel body, and a curvature of the protection layer at any point on a surface of a side away from the panel body is not 0.

18. The display panel of claim 17, wherein the edge subportions are adhered to the protection layer, and a curvature of the edge subportions at any point on a surface of a side close to the protection layer is not 0.

19. A display device comprising a display panel,
wherein the display panel comprises:
a panel body, and the panel body has a main body portion, a bonding portion disposed on a backlight side of the main body portion, and a bending portion connected between the main body portion and the bonding portion, wherein the bending portion is connected to a first side of the main body portion, and the bending portion comprises at least one edge subportion, wherein the edge subportions are disposed at both ends of the bending portion in a first direction and the edge subportions are disposed on a side of the bending portion close to the main body portion, wherein the first direction is parallel to a direction of extension of the first side of the main body portion, and wherein the panel body comprises:
a substrate disposed in the main body portion, the bending portion and the bonding portion;
a first inorganic layer disposed on a side of the substrate;
a second inorganic layer disposed on a side of the first inorganic layer away from the substrate; and
a first organic layer disposed between the first inorganic layer and the second inorganic layer;
wherein the first organic layer is spaced between the first inorganic layer and the second inorganic layer within the edge subportions; or
the second inorganic layer is disposed outside the edge subportions and the second inorganic layer is disposed between two edge subportions in the first direction.

20. The display device of claim 19, wherein the first inorganic layer comprises a first subsegment disposed in the edge subportions, the second inorganic layer comprises a second subsegment disposed in the edge subportions, the first organic layer comprises a first organic subsegment disposed in the edge subportions, and the first organic subsegment is spaced between the first subsegment and the second subsegment.
